(19) United States
(12) Patent Application Publication
(10) Pub. No.: US 2025/0057013 A1
(43) Pub. Date: Feb. 13, 2025

(54) DISPLAY DEVICE AND METHOD FOR MANUFACTURING THE SAME

(71) Applicant: Samsung Display Co., LTD., Yongin-si (KR)

(72) Inventors: Yeon Guk KIM, Yongin-si (KR); Hee Yeon PARK, Yongin-si (KR); Chang Yeong SONG, Yongin-si (KR); Hye In JUNG, Yongin-si (KR); Yong Chan JU, Yongin-si (KR); Jae Heung HA, Yongin-si (KR)

(21) Appl. No.: 18/662,824

(22) Filed: May 13, 2024

(30) Foreign Application Priority Data
Aug. 9, 2023 (KR) 10-2023-0104118

(51) Int. Cl. H10K 59/80; C08G 77/12; C08G 77/20; C08G 77/50; C09D 183/04; C09D 183/14; H10K 59/12

(52) U.S. Cl. CPC H10K 59/873; C08G 77/12; C08G 77/20; C08G 77/50; C09D 183/04; C09D 183/14; H10K 59/1201

(57) ABSTRACT

A display device includes a substrate including a display area and a first non-display area around the display area; a light emitting element on the display area of the substrate in the display area; a lower inorganic encapsulation film on the substrate in the display area and the first non-display area; an organic encapsulation film on the lower inorganic encapsulation film; an upper inorganic encapsulation film on the organic encapsulation film; and a first dam between the lower inorganic encapsulation film and the upper inorganic encapsulation film in the first non-display area, wherein a first side surface of the first dam is in contact with the organic encapsulation film, and a second side surface of the first dam different from the first side surface of the first dam is in contact with the upper inorganic encapsulation film.

### CROSS-REFERENCE TO RELATED APPLICATION

The present application claims priority to and the benefit of Korean Patent Application No. 10-2023-0104118, filed on Aug. 9, 2023, in the Korean Intellectual Property Office, the entire content of which is incorporated herein by reference.

### BACKGROUND

### 1. Field

Embodiments of the present disclosure described herein are related to a display device and a method for manufacturing the same.

### 2. Description of the Related Art

As the information society/technology develops, the demand or desire for display devices for displaying images has increased and diversified. The display devices may be flat panel display devices such as liquid crystal display devices, field emission display devices, or organic light emitting display devices. Among such flat panel display devices, a light emitting display device may display an image without a backlight unit providing light to a display panel because each pixel of the display panel includes one or more light emitting elements that may be configured to emit light by themselves.

The display device includes a display area displaying an image and a non-display area disposed around the display area, for example, disposed to surround the display area. Recently, a width of the non-display area has been reduced in order to increase a degree of immersion in the display area and increase aesthetics of the display device.

### SUMMARY

Aspects according to one or more embodiments of the present disclosure are directed toward a display device having a non-display area of which a width is small and having excellent or suitable moisture permeation prevention performance, and a method for manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given herein.

According to an embodiment of the present disclosure, a display device includes a substrate including a display area and a first non-display area disposed around the display area; a light emitting element disposed on the display area of the substrate in the display area; a lower inorganic encapsulation film disposed on the substrate in the display area and the first non-display area; an organic encapsulation film disposed on the lower inorganic encapsulation film; an upper inorganic encapsulation film disposed on the organic encapsulation film; and a first dam disposed between the lower inorganic encapsulation film and the upper inorganic encapsulation film in the first non-display area, wherein a first side surface of the first dam is in contact with the organic encapsulation film, and a second side surface of the first dam different from the first side surface of the first dam is in contact with the upper inorganic encapsulation film.

According to an embodiment, a lower surface of the first dam may be in contact with the lower inorganic encapsulation film.

According to an embodiment, the first dam may include polysiloxane.

According to an embodiment, a glass transition temperature of the first dam may be about −180° C. to about −50° C.

According to an embodiment, a density of the first dam may be about 0.05 g/mL to about 5 g/mL.

According to an embodiment, a Young's modulus of the first dam may be 0.01 MPa to 1.0 MPa.

According to an embodiment, the first dam may include a compound represented by any one of Formulas 1 to 3:

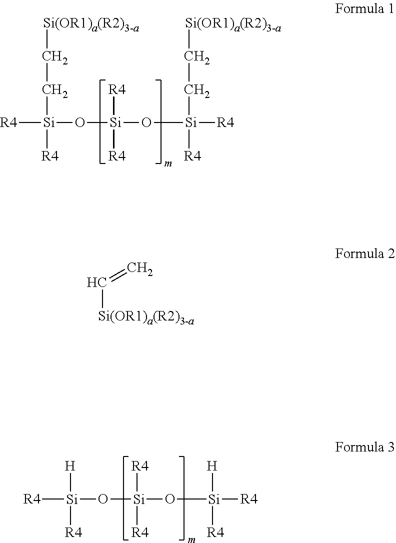

wherein a is an integer of 1 to 3,
m is an integer of 1 or more,
R1 is a substituted or unsubstituted alkyl group, a substituted or unsubstituted aryl group, or is represented by Formula S1,

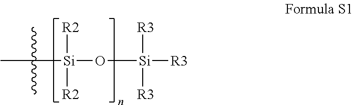

n is an integer of 1 or more,
R2 to R4 may each independently be the same as or different from each other, and may each independently be a substituted or unsubstituted alkyl group, a substituted or unsubstituted aryl group, a substituted or unsubstituted alkenyl group, or an oxygen atom, and/or are connected to an adjacent substituent to form a substituted or unsubstituted ring, and
a substituent in the “substituted or unsubstituted” is one or more substituents selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group, and/or a substituent in which two or more groups selected from the group are connected to each other.

According to an embodiment, the display device may further include a groove positioned between the light emitting element and the first dam.

According to an embodiment, the substrate may further include a through hole and a second non-display area disposed between the through hole and the display area, the display device further includes a first hole dam disposed between the lower inorganic encapsulation film and the upper inorganic encapsulation film in the second non-display area, a first side surface of the first hole dam is in contact with the organic encapsulation film, and a second side surface of the first hole dam different from the first side surface of the first hole dam is in contact with the upper inorganic encapsulation film.

According to an embodiment, the first hold dam may include the same material as the first dam.

According to an embodiment, the display device may further include a hole groove positioned between the light emitting element and the first hold dam.

According to an embodiment of the present disclosure, a display device includes a substrate including a display area and a first non-display area around (e.g., surrounding) an outer side of the display area; a lower inorganic encapsulation film disposed on the substrate in the display area and the first non-display area; an organic encapsulation film disposed on the lower inorganic encapsulation film; a first dam disposed on the substrate in the first non-display area and including polysiloxane; and an upper inorganic encapsulation film disposed on the organic encapsulation film and the first dam, wherein a first side surface of the first dam overlaps the organic encapsulation film in a thickness direction (e.g., in a plan view) of the substrate, and a second side surface of the first dam different from the first side surface of the first dam does not overlap the organic encapsulation film in the thickness direction of the substrate.

According to an embodiment, the first side surface and the second side surface of the first dam may overlap the upper inorganic encapsulation film and the lower inorganic encapsulation film in the thickness direction of the substrate.

According to an embodiment, a component of the first dam in an area adjacent to the substrate and a component of the first dam in an area adjacent to the upper inorganic encapsulation film may be the same as each other.

According to an embodiment, the first dam may include a compound represented by any one of Formulas 1 to 3:

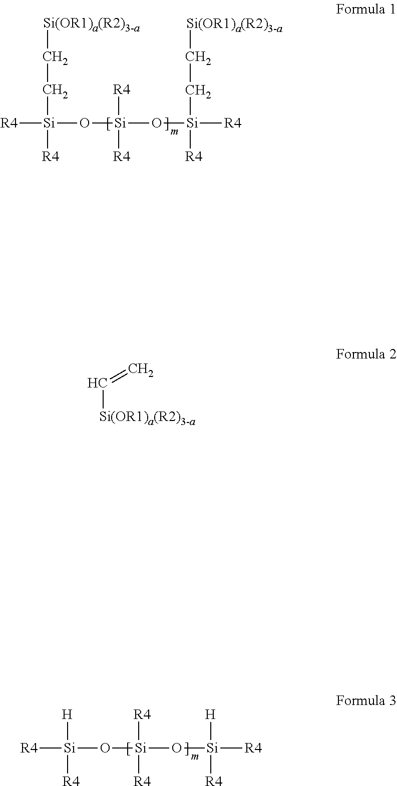

wherein a is an integer of 1 to 3,
m is an integer of 1 or more,
R1 is a substituted or unsubstituted alkyl group, a substituted or unsubstituted aryl group, or is represented by Formula S1,

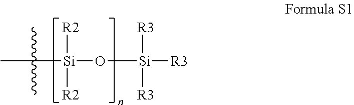

n is an integer of 1 or more,
R2 to R4 may each independently be the same as or different from each other, and may each independently be a substituted or unsubstituted alkyl group, a substituted or unsubstituted aryl group, a substituted or unsubstituted alkenyl group, or an oxygen atom, and/or are connected to an adjacent substituent to form a substituted or unsubstituted ring, and
a substituent in the “substituted or unsubstituted” is one or more substituents selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group, and/or a substituent in which two or more groups selected from the group are connected to each other.

According to an embodiment of the present disclosure, a method for manufacturing a display device includes applying (e.g., forming) light emitting elements on a substrate; depositing a lower inorganic encapsulation film on the light emitting elements; applying a dam composition onto the lower inorganic encapsulation film in a non-display area disposed around a display area in which the light emitting elements are disposed; and applying an organic encapsulation composition onto the lower inorganic encapsulation film in the display area.

According to an embodiment, a viscosity of the dam composition may be greater than a viscosity of the organic encapsulation composition.

According to an embodiment, in the applying of the dam composition onto the lower inorganic encapsulation film, a jet dispenser may be utilized.

According to an embodiment, the method for manufacturing a display device may include curing the organic encapsulation composition to form an organic encapsulation film; curing the dam composition to form a dam; and depositing an upper inorganic encapsulation film on the organic encapsulation film and the dam.

According to an embodiment, in the curing of the organic encapsulation composition to form the organic encapsulation film, the organic encapsulation composition may be cured utilizing light, and in the curing of the dam composition to form the dam, the dam composition may be cured utilizing heat.

According to an embodiment, a display device may have improved moisture permeation prevention performance.

According to an embodiment, the display device may have a non-display area of which a width is small.

The effects of the present disclosure are not limited to the aforementioned effects, and one or more suitable other effects are included in the present specification.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to an embodiment;

FIG. 2 is a plan view illustrating a display panel according to an embodiment;

FIG. 3 is a cross-sectional view illustrating an example of the display device taken along line I-I′ of FIG. 1;

FIG. 4 is a cross-sectional view illustrating an example of the display device in which a circuit board of FIG. 3 is bent;

FIG. 5 is a cross-sectional view of a display area of the display device according to an embodiment;

FIG. 6 is an enlarged plan view of area A1 in FIG. 2;

FIG. 7 is a cross-sectional view illustrating an example of the display panel taken along line II-II′ of FIG. 6;

FIG. 8 is an enlarged cross-sectional view of area A3 of FIG. 7 illustrating an example of the display panel;

FIG. 9 is an enlarged plan view of an edge area of a display device according to another embodiment;

FIG. 10 is a cross-sectional view of a display panel according to FIG. 9;

FIG. 11 is an enlarged plan view of a through hole portion, that is, area A2, of FIG. 2;

FIG. 12 is a cross-sectional view illustrating an example of a display panel taken along line III-III′ of FIG. 11;

FIG. 13 is an enlarged cross-sectional view of area A4 of FIG. 12 illustrating an example of the display panel;

FIG. 14 is an enlarged plan view of a through hole and a surrounding area of a display device (e.g., an area around the display device) according to another embodiment;

FIG. 15 is a cross-sectional view of a display panel according to FIG. 14;

FIG. 16 is a flowchart illustrating processes for manufacturing the display device according to an embodiment; and

FIGS. 17-25 are cross-sectional views or plan views sequentially illustrating the processes for manufacturing the display device according to an embodiment.

### DETAILED DESCRIPTION

The present disclosure will now be described more fully hereinafter with reference to the accompanying drawings, in which preferred embodiments of the present disclosure are shown. This present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be utilized herein to describe one or more suitable elements, these elements should not be limited by these terms. These terms are only utilized to distinguish one element from another element. For instance, a first element discussed herein could be termed a second element without departing from the teachings of the present disclosure. Similarly, the second element could also be termed the first element.

Hereinafter, embodiments will be described with reference to the accompanying drawings.

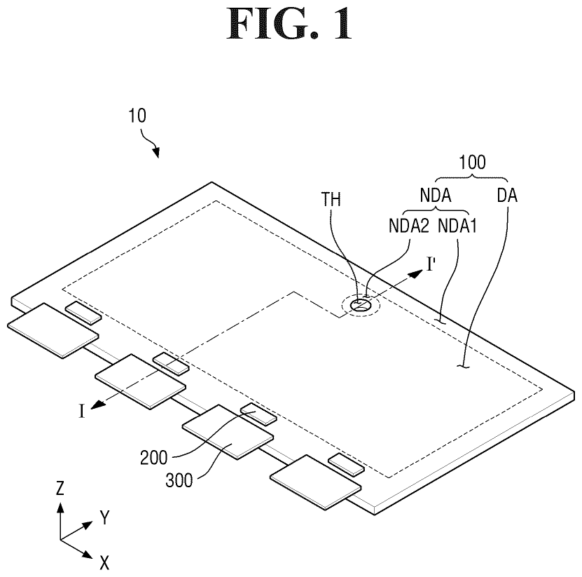

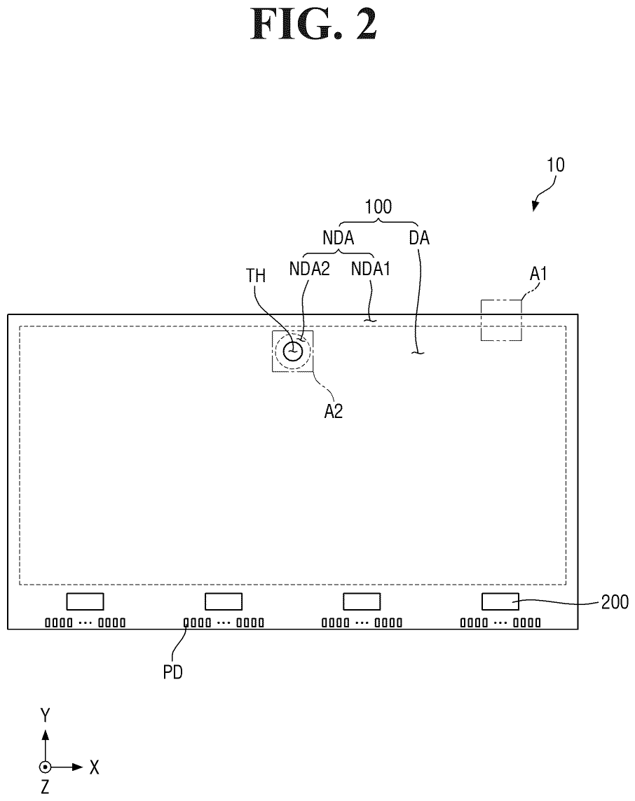

FIG. 1 is a perspective view illustrating a display device according to an embodiment. FIG. 2 is a plan view illustrating a display panel according to an embodiment.

Referring to FIG. 1, a display device 10 according to an embodiment is a device that displays a moving image or a still image, and may be utilized as a display screen of one or more suitable products such as televisions, laptop computers, monitors, billboards, and the Internet of Things (IOT) devices as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display device 10 according to an embodiment may be a light emitting display device such as an organic light emitting display device utilizing an organic light emitting diode, a quantum dot light emitting display device including a quantum dot light emitting layer, an inorganic light emitting display device including an inorganic semiconductor, and a micro light emitting display device utilizing a micro or nano light emitting diode (micro LED or nano LED). Hereinafter, it will be mainly described that the display device 10 is the organic light emitting display, but the present disclosure is not limited thereto.

The display device 10 according to an embodiment may include a display panel 100, display drivers 200, and circuit boards 300.

The display panel 100 may be formed in a rectangular shape, in a plan view, having long sides in a first direction (X-axis direction) and short sides in a second direction (Y-axis direction) crossing the first direction (X-axis direction). A corner where the long side in the first direction (X-axis direction) and the short side in the second direction (Y-axis direction) meet may be right-angled or rounded with a curvature. The shape of the display panel 100 in the plan view is not limited to the rectangular shape, and may be other polygonal shapes, a circular shape, or an elliptical shape.

The display panel 100 may be formed to be flat, but is not limited thereto. For example, the display panel 100 may include curved surface portions formed at left and right ends thereof and having a constant curvature or a variable curvature. In some embodiments, the display panel 100 may be flexibly formed to be curved, bent, folded, or rolled.

The display panel 100 may include a display area DA that displays an image and a non-display area NDA that does not display an image.

The display area DA may occupy most of the area of the display panel 100. The display area DA may be disposed at the center of the display panel 100. Pixels each including a plurality of emission areas in order to display an image may be disposed in the display area DA.

The non-display area NDA may include a first non-display area NDA1 and a second non-display area NDA2. The first non-display area NDA1 may be disposed to neighbor to the display area DA. The first non-display area NDA1 may be an area outside the display area DA. The first non-display area NDA1 may be disposed to surround the display area DA. The first non-display area NDA1 may be an edge area of the display panel 100.

A through hole TH may be selectively disposed inside the display area DA. The second non-display area NDA2 may be positioned to surround the through hole TH, and may be disposed between the display area DA and the through hole TH. The through hole TH is a hole capable of transmitting light therethrough, and may be an area in which an optical device OPD is disposed.

Referring to FIGS. 1 and 2, the first non-display area NDA1 may include display pads PD, the display drivers 200, and the circuit boards 300.

The display pads PD may be disposed at one edge of the display panel 100. For example, the display pads PD may be disposed at a lower edge of the display panel 100. The display pads PD may be connected to the display drivers 200 and the circuit boards 300.

The display drivers 200 may generate and output signals and voltages for driving the display panel 100. For example, the display drivers 200 may generate and output data voltages, source voltages, scan timing signals, and/or the like. The display drivers 200 may supply source voltages to power lines and supply gate control signals to a gate driver.

The display drivers 200 may be disposed between the display pads PD and the display area DA in the first non-display area NDA1. The display drivers 200 may be attached to the first non-display area NDA1 of the display panel 100 in a chip on glass (COG) manner. In some embodiments, the display drivers 200 may be attached to the circuit boards 300 in a COP (chip on plastic) manner.

The circuit boards 300 may be disposed on one edge of the display panel 100, and may be disposed on the display pads PD. The circuit boards 300 may be attached to the display pads PD utilizing a conductive adhesive member such as an anisotropic conductive film and an anisotropic conductive adhesive. Accordingly, the circuit boards 300 may be electrically connected to signal lines of the display panel 100. Each of the circuit boards 300 may be a flexible printed circuit board or a flexible film such as a chip on film.

In some embodiments, a bending area BA may be disposed between the display driver 200 and the display area DA in the first non-display area NDA1. The bending area BA may be an area in which the display drivers 200 and the circuit boards 300 are bent to be disposed below the display panel 100. The display drivers 200 and the circuit boards 300 bent by the bending area BA may overlap the display area DA in a third direction (Z-axis direction).

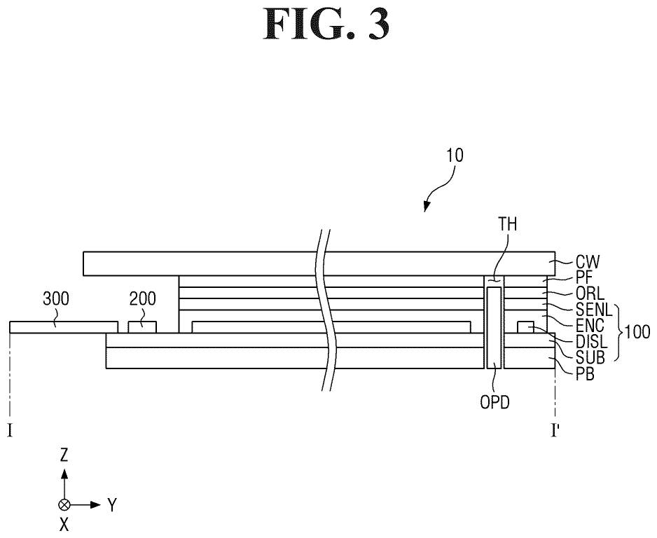

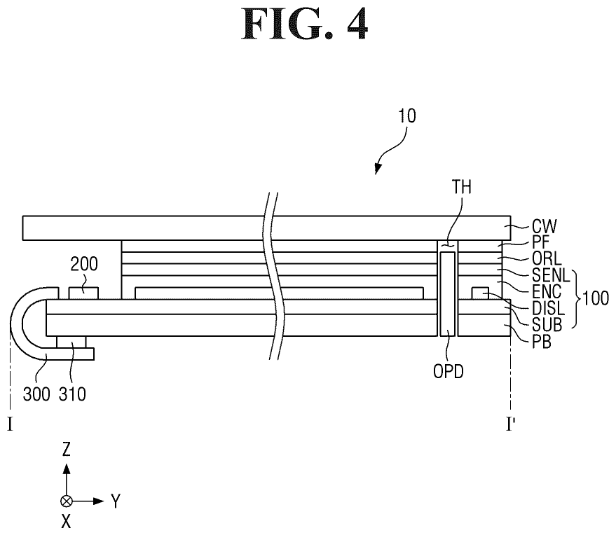

FIG. 3 is a cross-sectional view illustrating an example of the display device taken along line I-I′ of FIG. 1. FIG. 4 is a cross-sectional view illustrating an example of the display device in which a circuit board of FIG. 3 is bent.

Referring to FIG. 3, the display device 10 according to an embodiment may include a display panel 100, a polarizing film PF, a cover window CW, and a panel lower cover PB. The display panel 100 may include a substrate SUB, a thin film transistor layer TFTL, a light emitting element layer EML, a thin film encapsulation layer ENC, a touch sensor layer SENL, and an organic planarization layer ORL.

The substrate SUB may be a base substrate or a base member. The substrate SUB may be a flexible substrate that may be bent, folded, and rolled. For example, the substrate SUB may include a polymer resin such as polyimide (PI), but is not limited thereto. In another embodiment, the substrate SUB may include a glass material or a metal material.

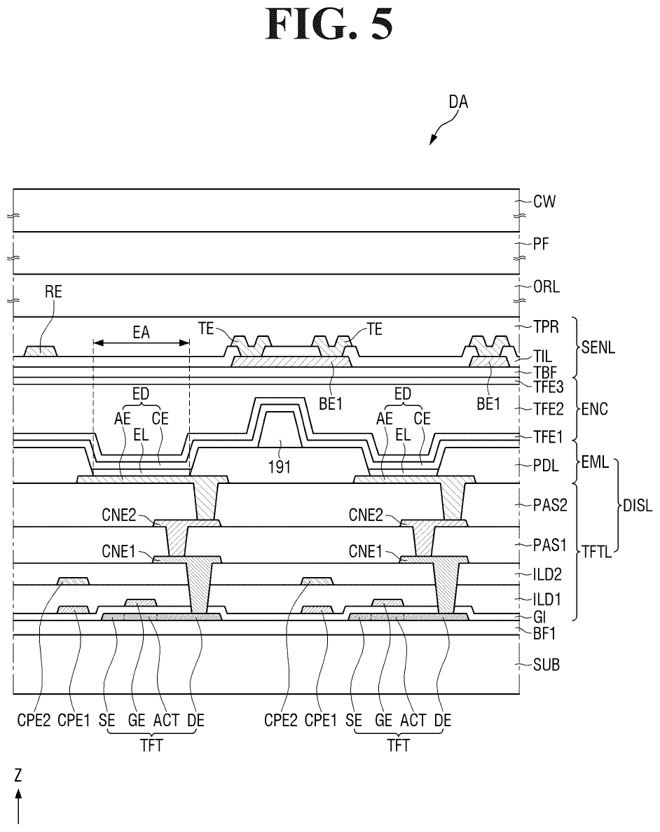

A display layer DISL may be disposed on an upper surface of the substrate SUB. The display layer DISL may be a layer displaying an image. The display layer DISL may include a thin film transistor layer TFTL (see FIG. 5) in which thin film transistors are formed and a light emitting element layer EML (see FIG. 5) in which light emitting elements emitting light are disposed in emission areas.

The thin film transistor layer TFTL may be disposed on the substrate SUB. The thin film transistor layer TFTL may include a plurality of thin film transistors. Each of the thin film transistors may include a semiconductor region, a source electrode, a drain electrode, and a gate electrode. In some embodiments, the thin film transistor layer TFTL may further include scan lines, data lines, power lines, and/or the like, in the display area. A scan driving circuit unit outputting scan signals to the scan lines, fan-out lines connecting the data lines and a driving integrated chip (IC) to each other, and/or the like, may be disposed in the non-display area NDA.

The light emitting element layer EML may be disposed on the thin film transistor layer TFTL. The light emitting element layer EML may include a plurality of light emitting elements ED each including a pixel electrode, a common electrode, and a light emitting layer to emit light and a pixel defining film PDL defining the pixels. The plurality of light emitting elements may be disposed in the display area DA.

The thin film encapsulation layer ENC may be positioned on the light emitting element layer EML. The thin film encapsulation layer ENC may cover an upper surface and side surfaces of the light emitting element layer EML in order to prevent or reduce oxygen or moisture from permeating into the light emitting element layer EML. The thin film encapsulation layer ENC may include at least one inorganic film and at least one organic film.

The touch sensor layer SENL may be disposed on the thin film encapsulation layer ENC. The touch sensor layer SENL may include sensor electrodes. The touch sensor layer SENL may sense a user's touch utilizing the sensor electrodes.

The organic planarization layer ORL may be disposed on the touch sensor layer SENL. The organic planarization layer ORL may planarize a step therebelow to facilitate attachment of the polarizing film PF thereon and prevent or reduce reflection of external light due to the polarizing film PF from being viewed by a user.

The polarizing film PF may be disposed on the organic planarization layer ORL. The polarizing film PF may be disposed on the display panel 100 in order to reduce external light reflection. The polarizing film PF may include a first base member, a linear polarizer, a phase retardation film such as a λ/4 plate (quarter-wave plate), and a second base member. The first base member, the phase retardation film, the linear polarizer, and the second base member of the polarizing film PF may be sequentially stacked on the display panel 100.

The cover window CW may be disposed on the polarizing film PF. The cover window CW may be attached onto the polarizing film PF by a transparent adhesive member such as an optically clear adhesive (OCA) film.

The panel lower cover PB may be disposed on a lower surface of the substrate SUB. The lower surface of the substrate SUB may be a surface opposite to the upper surface of the substrate SUB. In other words, the lower surface of the substrate SUB may be a surface opposite to a surface on which the thin film transistor layer TFTL, the light emitting element layer EML, the thin film encapsulation layer ENC, and the touch sensor layer SENL are positioned. The panel lower cover PB may be attached to the lower surface of the substrate SUB through an adhesive member. The adhesive member may be a pressure sensitive adhesive (PSA).

The panel lower cover PB may include at least one of a light blocking member for absorbing light incident from the outside, a buffer member for absorbing impact from the outside, or a heat dissipation member for efficiently dissipating heat.

The display device 10 may further include an optical device OPD. The optical device OPD may be configured to emit or receive light of infrared, ultraviolet, and visible light bands. For example, the optical device OPD may be an optical sensor sensing light incident on the display device 10, such as a proximity sensor, an illuminance sensor, and a camera sensor or an image sensor.

The optical device OPD may be disposed in the through hole TH. The through hole TH is a hole capable of transmitting light therethrough, and may be a physical hole penetrating through the panel lower cover PB, the display panel 100, and the polarizing film PF. However, the present disclosure is not limited thereto, and the through hole TH may penetrate through the panel lower cover PB, but may not penetrate through the display panel 100 and the polarizing film PF. The cover window CW may be disposed to cover the through hole TH.

Referring to FIG. 4, the display driver 200 and the circuit board 300 may be bent below the display panel 100. The circuit board 300 may be attached to a lower surface of the panel lower cover PB utilizing an adhesive member 310. The adhesive member 310 may be a pressure sensitive adhesive.

FIG. 5 is a cross-sectional view illustrating an example of a display area of the display panel according to an embodiment.

Referring to FIG. 5, the display panel 100 according to an embodiment may be a light emitting display panel including light emitting elements ED each including a light emitting layer EL. A common electrode CE in FIG. 5 may be formed not only in areas that overlap pixel electrodes AE, but also in an area that does not overlap pixel electrodes AE1 and AE2.

The display device 10 may include a plurality of emission areas EA1, EA2, and EA3 disposed in the display area DA. The emission areas EA1, EA2, and EA3 may include first emission areas EA1, second emission areas EA2, and third emission areas EA3 that emit light of different colors. The first to third emission areas EA1, EA2, and EA3 may be configured to emit red, green, or blue light, respectively, and colors of the light emitted from the respective emission areas EA1, EA2, and EA3 may be different from each other depending on types (kinds) of light emitting elements to be described later. As an example, the first emission area EA1 may be configured to emit a first light, which is the red light, the second emission area EA2 may be configured to emit a second light, which is the green light, and the third emission area EA3 may be configured to emit a third light, which is the blue light. However, the present disclosure is not limited thereto.

The first to third emission areas EA1, EA2, and EA3 may be defined by openings defined by a pixel defining film PDL to be described later, respectively.

In the display device 10, the first emission area EA1, the second emission area EA2, and the third emission area EA3 disposed adjacent to each other may form one pixel group. One pixel group may include the emission areas EA1, EA2, and EA3 configured to emit light of different colors to express a white gradation. However, the present disclosure is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, and/or the like.

Referring to FIG. 5, the display panel 100 may include a substrate SUB, a thin film transistor layer TFTL, a light emitting element layer EML, a thin film encapsulation layer ENC, and a touch sensor layer SENL.

The substrate SUB has already been described above, and a description thereof will thus not be provided.

The thin film transistor layer TFTL may include a first buffer layer BF1, thin film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic film capable of preventing or reducing permeation of air or moisture. For example, the first buffer layer BF1 may include a plurality of inorganic films that are alternately stacked.

The thin film transistor TFT may be disposed on the first buffer layer BF1, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the first buffer layer BF1. The semiconductor layer ACT may overlap the gate electrode GE in a thickness direction (e.g., in a plan view), and may be insulated from the gate electrode GE by the gate insulating layer GI. A material of the semiconductor layer ACT in portions of the semiconductor layer ACT may become conductors to form the source electrode SE and the drain electrode DE.

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT. For example, the gate insulating layer GI may cover the first buffer layer BF1 and the semiconductor layer ACT, and may insulate the semiconductor layer ACT and the gate electrode GE from each other. The gate insulating layer GI may include contact holes through which the first connection electrodes CNE1 penetrate.

The first interlayer insulating layer ILD1 may cover the gate electrode GE and the gate insulating layer GI. The first interlayer insulating layer ILD1 may include contact holes through which the first connection electrodes CNE1 penetrate. The contact holes of the first interlayer insulating layer ILD1 may be connected to the contact holes of the gate insulating layer GI and contact holes of the second interlayer insulating layer ILD2.

The capacitor electrodes CPE may be disposed on the first interlayer insulating layer ILD1. In an embodiment, the capacitor electrodes CPE may each include a plurality of capacitor electrodes, first capacitor electrodes CPE1 may be disposed on the gate insulating layer GI, and the second capacitor electrodes CPE2 may be disposed on the first interlayer insulating layer ILD1 and may overlap the first capacitor electrodes CPE1 in the thickness direction. In another embodiment, the capacitor electrode CPE overlaps the gate electrode GE in the thickness direction, such that the capacitor electrode CPE and the gate electrode GE may form capacitance.

The second interlayer insulating layer ILD2 may cover the capacitor electrodes CPE and the first interlayer insulating layer ILD1. The second interlayer insulating layer ILD2 may include contact holes through which the first connection electrodes CNE1 penetrate. The contact holes of the second interlayer insulating layer ILD2 may be connected to the contact holes of the first interlayer insulating layer ILD1 and the contact holes of the gate insulating layer GI.

The first connection electrodes CNE1 may be disposed on the second interlayer insulating layer ILD2. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer ILD2, the first interlayer insulating layer ILD1, and the gate insulating layer GI to be in contact with the drain electrode DE of the thin film transistor TFT. The first connection electrode CNE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first passivation layer PAS1 may cover the first connection electrode CNE1 and the second interlayer insulating layer ILD2. The first passivation layer PAS1 may protect the thin film transistor TFT. The first passivation layer PAS1 may include contact holes through which the second connection electrodes CNE2 penetrate.

The second connection electrodes CNE2 may be disposed on the first passivation layer PAS1. The second connection electrodes CNE2 may electrically connect the first connection electrodes CNE1 and pixel electrodes AE1, AE2, and AE3 of light emitting elements ED1, ED2, and ED3 to each other. The second connection electrode CNE2 may be inserted into the contact hole formed in the first passivation layer PAS1 to be in contact with the first connection electrode CNE1.

The second passivation layer PAS2 may cover the second connection electrodes CNE2 and the first passivation layer PAS1. The second passivation layer PAS2 may include contact holes through which the pixel electrodes AE1, AE2, and AE3 of the light emitting elements ED1, ED2, and ED3 penetrate.

The light emitting element layer EML may be disposed on the thin film transistor layer TFTL. Referring to FIG. 5, the light emitting element layer EML may include light emitting elements ED and a pixel defining film PDL.

The light emitting elements ED may be disposed on the second passivation layer PAS2. The light emitting element ED may include a pixel electrode AE, a light emitting layer EL, and a common electrode CE. Holes from the pixel electrode AE and electrons from the common electrode CE may be combined with each other in the light emitting layer EL to emit light.

The pixel electrodes AE may be disposed in a plurality of emission areas EA, respectively. The pixel electrodes AE may include a first pixel electrode AE disposed in the first emission area EA1, a second pixel electrode AE disposed in the second emission area EA2, and a third pixel electrode AE disposed in the third emission area EA3. The pixel electrodes AE may be disposed to be spaced apart from each other on the second passivation layer PAS2. The pixel electrodes AE may be disposed in different emission areas EA1, EA2, and EA3, respectively.

The pixel electrode AE may be electrically connected to the drain electrode DE of the thin film transistor TFT through the first and second connection electrodes CNE1 and CNE2. In an embodiment, the pixel electrode AE may have a stacked film structure in which a layer made of a material having a high work function, such indium tin oxide (ITO), indium zinc oxide (IZO), zinc oxide (ZnO), or indium oxide (In₂O₃) and a layer made of a reflective material such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or one or more mixtures thereof are stacked. The layer made of the material having the high work function may be disposed at a layer above the layer made of the reflective material to be disposed close to the light emitting layer EL. As an example, the pixel electrode AE may have a multilayer structure of ITO/Mg, ITO/MgF, ITO/Ag, and ITO/Ag/ITO, but is not limited thereto.

The pixel defining film PDL may be positioned on the second passivation layer PAS2 and the pixel electrodes AE, but may expose at least portions of the pixel electrodes AE. The pixel defining film PDL may define the emission areas EA1, EA2, and EA3. The pixel defining film PDL may cover edges of the pixel electrodes AE.

The pixel defining film PDL may include an organic or inorganic insulating material. As an example, the pixel defining film PDL may be an organic film made of an acrylic resin, an epoxy resin, a phenolic resin, a polyamide resin, a polyimide resin, and/or the like. As another example, the pixel defining film PDL may include one or more inorganic insulating materials selected from among aluminum oxide, titanium oxide, tantalum oxide, hafnium oxide, zinc oxide, silicon oxide, silicon nitride, and silicon oxynitride.

In an embodiment, a spacer 191 may be disposed on the pixel defining film PDL. The spacer 191 may serve to support a mask during a process of manufacturing the light emitting layer EL. The spacer 191 may be formed as an organic film made of an acrylic resin, an epoxy resin, a phenolic resin, a polyamide resin, a polyimide resin, and/or the like.

The light emitting layer EL is formed on the pixel electrode AE. The light emitting layer EL may include an organic material to emit light of a set or predetermined color. For example, the light emitting layer EL may include a hole transporting layer, an organic material layer, and an electron transporting layer. The organic material layer may include a host and a dopant. The organic material layer may include a material emitting set or predetermined light, and may be formed utilizing a phosphorescent material or a fluorescent material.

The common electrode CE is formed on the light emitting layer EL. The common electrode CE may be formed to cover the light emitting layer EL. According to an embodiment, the common electrode CE may be a common layer formed in common in the emission areas EA1 and EA2 as illustrated in FIG. 5.

The common electrode CE may include a transparent conductive material to emit the light generated from the light emitting layer EL. As an example, the common electrode CE may include silver (Ag), but is not limited thereto. The common electrode CE may include a material layer having a small work function, such as Li, Ca, LiF/Ca, LiF/Al, Al, Mg, Pt, Pd, Ni, Au, Nd, Ir, Cr, BaF, Ba, or one or more compounds or mixtures thereof (e.g., a mixture of Ag and Mg, etc.). The common electrode CE may further include a transparent metal oxide layer disposed on the material layer having the small work function.

A capping layer may be disposed on the common electrode CE. The capping layer may include an inorganic insulating material and cover the light emitting elements ED. The capping layer may prevent or reduce the light emitting elements ED from being damaged by external air. In an embodiment, the capping layer may include aluminum oxide, titanium oxide, tantalum oxide, hafnium oxide, zinc oxide, silicon oxide, silicon nitride, and silicon oxynitride.

The thin film encapsulation layer ENC may cover the light emitting element layer EML. The thin film encapsulation layer ENC may completely cover the common electrode CE.

The thin film encapsulation layer ENC may include at least one inorganic film to prevent or reduce oxygen or moisture from permeating into the light emitting element layer EML. The thin film encapsulation layer ENC may include at least one organic film to protect the light emitting element layer EML from foreign substances such as dust. In an embodiment, the thin film encapsulation layer ENC may include a lower inorganic encapsulation film TFE1, an organic encapsulation film TFE2, and an upper inorganic encapsulation film TFE3 that are sequentially stacked. The lower inorganic encapsulation film TFE1 and the upper inorganic encapsulation film TFE3 may be inorganic encapsulation layers, and the organic encapsulation film TFE2 disposed between the lower inorganic encapsulation film TFE1 and the upper inorganic encapsulation film TFE3 may be an organic encapsulation layer.

Each of the lower inorganic encapsulation film TFE1 and the upper inorganic encapsulation film TFE3 may include one or more inorganic insulating materials. The inorganic insulating material may include aluminum oxide, titanium oxide, tantalum oxide, hafnium oxide, zinc oxide, silicon oxide, silicon nitride, and silicon oxynitride.

The organic encapsulation film TFE2 may include a polymer-based material. The polymer-based material may include an acrylic resin, an epoxy-based resin, polyimide, polyethylene, and/or the like. For example, the organic encapsulation film TFE2 may include an acrylic resin such as polymethyl methacrylate or polyacrylic acid. The organic encapsulation film TFE2 may be formed by curing a monomer or applying a polymer.

The touch sensor layer SENL may be disposed on the thin film encapsulation layer ENC. The touch sensor layer SENL may include a touch buffer layer TBF, a touch insulating layer TIL, touch electrodes TE, and a touch protection layer TPR.

The touch buffer layer TBF may be disposed on the thin film encapsulation layer ENC. The touch buffer layer TBF may have insulating and optical functions. The touch buffer layer TBF may include at least one inorganic film. Optionally, the touch buffer layer TBF may not be provided. In some embodiments, a connection electrode electrically connecting the touch electrodes to each other may be disposed on the touch buffer layer TBF. The connection electrode may be formed as a single layer made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The touch insulating layer TIL may cover the touch buffer layer TBF. The touch insulating layer TIL may have an insulating function. For example, the touch insulating layer TIL may be an inorganic film including at least one of a silicon nitride layer, a silicon oxynitride layer, a silicon oxide layer, a titanium oxide layer, or an aluminum oxide layer.

Some of the touch electrodes TE may be disposed on the touch insulating layer TIL. Each of the touch electrodes TE may not overlap the first to third emission areas EA1, EA2, and EA3. Each of the touch electrodes TE may be formed as a single layer made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/Al/ITO) of aluminum and ITO, an APC alloy (e.g., Ag-alloy or Ag—Pd—Cu alloy), and a stacked structure (ITO/APC/ITO) of an APC alloy and ITO.

The touch protection layer TPR may cover the touch electrodes TE and the touch insulating layer TIL. The touch protection layer TPR may have insulating and optical functions. The touch protection layer TPR may be made of the material included in the touch insulation layer TIL.

A light blocking layer may be disposed on the touch sensor layer SENL. The light blocking layer may be disposed to overlap the pixel defining film PDL. The light blocking layer may include a light absorbing material. For example, the light blocking layer may include an inorganic black pigment or an organic black pigment. The inorganic black pigment may be carbon black, and the organic black pigment may include at least one of lactam black, perylene black, or aniline black, but the present disclosure is not limited thereto. The light blocking layer may prevent or reduce color mixing due to permeation of visible light between the first to third emission areas EA1, EA2, and EA3 to improve a color gamut of the display device 10.

In an embodiment, a color filter layer may be disposed on each of the touch protection layer TPR and the light blocking layer so as to overlap the emission areas EA1, EA2, and EA3.

The color filter layer may include a first color filter, a second color filter, and a third color filter disposed to each correspond to the different emission areas EA1, EA2, and EA3. A plurality of color filters may include colorants such as dyes or pigments configured to absorb light of wavelength bands other than light of a specific wavelength band, and may be disposed to correspond to the colors of the light configured to emit from the emission areas EA1, EA2, and EA3. For example, the first color filter may be a red color filter disposed to overlap the first emission area EA1 and configured to transmit only the first light, which is the red light, therethrough. The second color filter may be a green color filter disposed to overlap the second emission area EA2 and configured to transmit only the second light, which is the green light, therethrough, and the third color filter may be a blue color filter disposed to overlap the third emission area EA3 and configured to transmit only the third light, which is the blue light, therethrough.

An organic planarization layer ORL may be disposed on the touch sensor layer SENL. The organic planarization layer ORL may planarize a step therebelow to facilitate attachment of the polarizing film PF thereon and prevent or reduce reflection of external light due to the polarizing film PF from being viewed by a user.

The organic planarization layer ORL may include an overcoat layer OC. The overcoat layer OC may be made of an organic materials, and may include, for example, an acrylic resin, an epoxy resin, a phenolic resin, a polyamide resin, a polyimide resin, and/or the like.

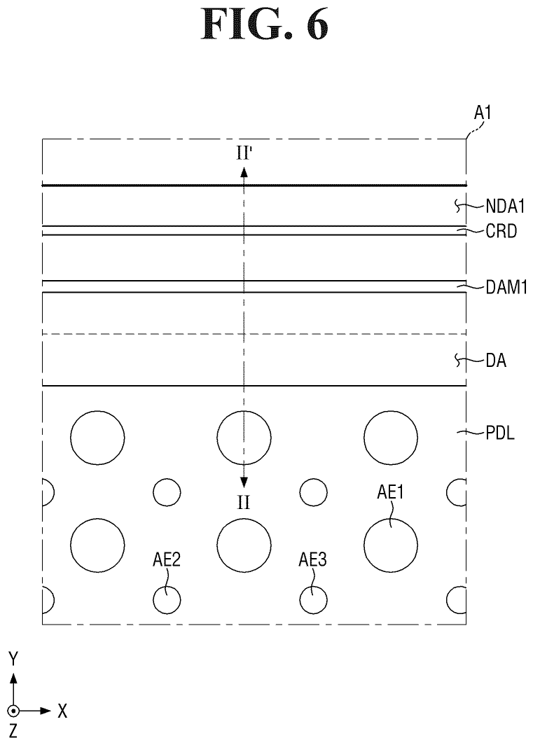

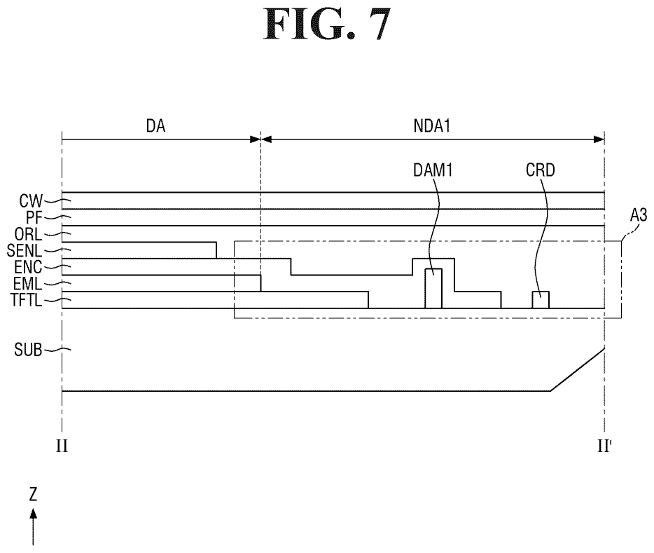

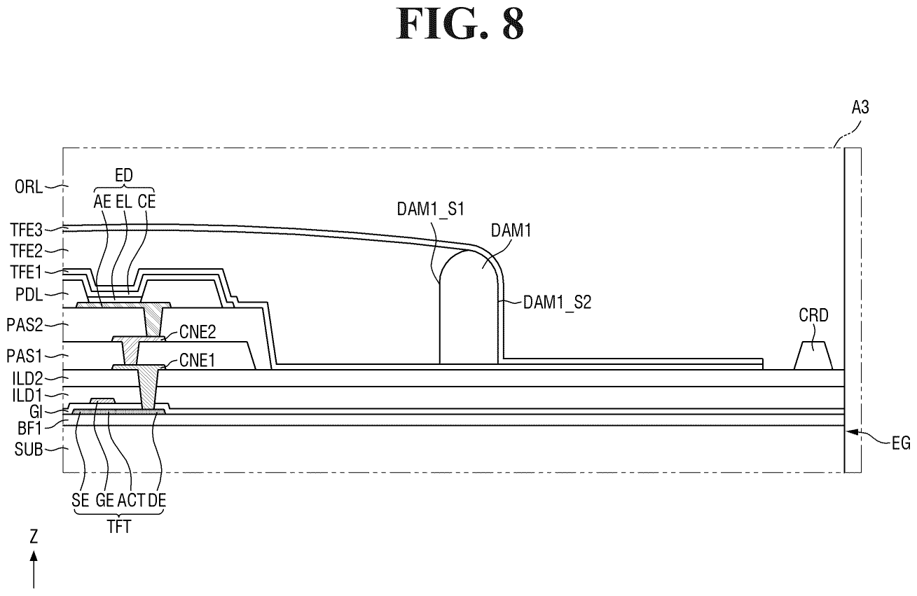

FIG. 6 is an enlarged view of an edge area of the display device. FIG. 6 is an enlarged plan view of area A1 in FIG. 2, and FIG. 7 is a cross-sectional view illustrating an example of the display device taken along line II-II′ of FIG. 6. FIG. 8 is an enlarged cross-sectional view of area A3 in FIG. 7.

Referring to FIGS. 6 to 8, the light emitting elements ED may be disposed in the emission areas EA1, EA2, and EA3 of the display area DA, and the first non-display area NDA1 may be disposed around the display area DA. The display area DA may be defined as the light emitting element layer EML including the light emitting elements ED and the pixel defining film PDL. The first non-display area NDA1 may be formed to surround an edge of the display area DA. A first dam DAM1 may be disposed in the first non-display area NDA1, and a crack dam CRD may be disposed outside the first dam DAM1.

The thin film encapsulation layer ENC may overlap the light emitting element layer EML and the first dam DAM1 in a thickness direction Z (e.g., in a plan view or Z-axis direction) of the substrate SUB. In some embodiments, the thin film encapsulation layer ENC may overlap the crack dam CRD as well as the light emitting element layer EML and the first dam DAM1.

The first dam DAM1 may be formed in order to prevent or reduce an organic material in the display area DA from overflowing into the non-display area NDA. As an example, in the first non-display area NDA1, the organic encapsulation film TFE2 may not flow into the first non-display area NDA1 by the first dam DAM1.

The first dam DAM1 may be positioned to overlap the first non-display area NDA1 and surround the display area. The first dam DAM1 may be disposed between the lower inorganic encapsulation film TFE1 and the upper inorganic encapsulation film TFE3.

A first side surface DAM1_S1 of the first dam DAM1 may overlap the organic encapsulation film TFE2 in the thickness direction Z of the substrate SUB. The first side surface DAM1_S1 of the first dam DAM1 may be in contact with the organic encapsulation film TFE2. The first side surface DAM1_S1 of the first dam DAM1 may be a side surface facing the display area DA.

A second side surface DAM1_S2 of the first dam DAM1 may be in contact with the upper inorganic encapsulation film TFE3. The second side surface DAM1_S2 of the first dam DAM1 may not overlap the organic encapsulation film TFE2 in the thickness direction Z of the substrate SUB. The second side surface DAM1_S2 of the first dam DAM1 may not be in contact with the organic encapsulation film TFE2. The second side surface DAM1_S2 of the first dam DAM1 is a side surface different from the first side surface DAM1_S1, and may be a surface opposite to the first side surface DAM1_S1. The organic encapsulation film TFE2 may be surrounded by the first side surface DAM1_S1 of the first dam DAM1, and may not flow onto the second side surface DAM1_S2 of the first dam DAM1.

The first side surface DAM1_S1 and the second side surface DAM1_S2 of the first dam DAM1 may overlap the lower inorganic encapsulation film TFE1 and the upper inorganic encapsulation film TFE3 in the thickness direction Z of the substrate SUB. The first side surface DAM1_S1 and the second side surface DAM1_S2 of the first dam DAM1 may include not only surfaces perpendicular to the substrate SUB but also surfaces inclined with respect to the substrate SUB or curved surfaces. A lower surface of the first dam DAM1 may be in contact with the lower inorganic encapsulation film TFE1.

The first dam DAM1 may include polysiloxane. The polysiloxane is an organic material, and may have excellent or suitable adhesion with the organic encapsulation film TFE2 to prevent or reduce the organic encapsulation film TFE2 from overflowing the first dam DAM1.

In an embodiment, a glass transition temperature (Tg) of the first dam DAM1 may be about −180° C. to about −50° C. In another embodiment, a glass transition temperature (Tg) of the first dam DAM1 may be about −130° C. to about −100° C. The glass transition temperature (Tg) may be measured in a temperature range of about 50° C. to about 400° C. with a fixed tension force of about 0.05 N and at a temperature rising rate of about 5° C./min, utilizing a thermal mechanical analyzer (TMA Q400 available from TA Instruments) or may be measured according to ASTM D7028.

In an embodiment, a density of the first dam DAM1 may be about 0.05 g/mL to about 5 g/mL. In another embodiment, a density of the first dam DAM1 may be about 0.05 g/mL to about 2.5 g/mL. The density may be measured according to ASTM D792.

In an embodiment, a Young's modulus of the first dam DAM1 may be about 0.01 MPa to about 1.0 Mpa. In another embodiment, a Young's modulus of the first dam DAM1 may be about 0.01 Mpa to about 0.06 Mpa. The Young's modulus is a value in the range of strain of about 0 to about 5% on an s-s curve measured by applying a force to a sample of about 4 to about 6 mm (L)×about 5.3 mm (W)×about 0.06 mm (T) while increasing the force by about 1 N per minute so as to reach about 18 N, under an isothermal temperature of about 25° C. utilizing a dynamic mechanical analyzer (DMA).

The first dam DAM1 may be a single layer. A component of the first dam DAM1 in an area adjacent to the substrate SUB and a component of the first dam DAM1 in an area adjacent to the upper inorganic encapsulation film TFE3 may be the same as each other. The first dam DAM1 may overlap the light emitting element ED and the organic encapsulation film TFE2 in a first direction (e.g., a horizontal direction or an X-axis direction) of the substrate SUB.

The polysiloxane of the first dam DAM1 may be an oligomer or a polymer, which is a combination of a silicon-vinyl based compound and a silicon-hydride based compound.

The silicon-vinyl based compound may be a compound represented by Formula (2). The silicon-hydride based compound may be a compound represented by Formula (3). The polysiloxane, which is the combination of the silicon-vinyl based compound and the silicon-hydride based compound, may be a compound represented by Formula (1).

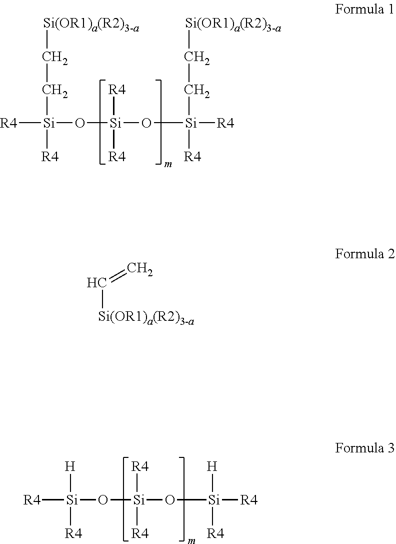

Here, a is an integer of 1 to 3,
m is an integer of 1 or more,
R1 is a substituted or unsubstituted alkyl group, a substituted or unsubstituted aryl group, or is represented by Formula S1,

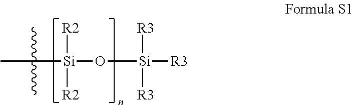

n is an integer of 1 or more,
R2 to R4 may each independently be the same as or different from each other, and may each independently be a substituted or unsubstituted alkyl group, a substituted or unsubstituted aryl group, a substituted or unsubstituted alkenyl group, or an oxygen atom, and/or are connected to an adjacent substituent to form a substituted or unsubstituted ring, and
a substituent in the “substituted or unsubstituted” is one or more substituents selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group, and/or a substituent in which two or more groups selected from the group are connected to each other.

The alkyl group may have 1 to 30 carbon atoms, the alkenyl group may have 2 to 30 carbon atoms, the aryl group may have 6 to 60 carbon atoms, and the heterocyclic group may have 2 to 60 carbon atoms.

In Formula S1,

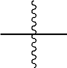

is a position connected to Formula 1 or 2.

A plurality of R1 may be the same or different from each other. A plurality of R2 may be the same or different from each other. A plurality of R3 may be the same or different from each other. A plurality of R4 may be the same or different from each other. A plurality of a may be the same or different from each other.

The silicon-vinyl based compound may include a linear form and a bulky form. In an embodiment, the silicon-vinyl compound may include a linear compound represented by Formula 2 and a bulky compound represented by Formula 2. In an embodiment, a content (e.g., amount) of the bulky compound represented by Formula 2 may be more than a content (e.g., amount) of the linear compound represented by Formula 2.

The linear compound among the silicon-vinyl compounds of Formula 2 may be the following compound. However, the present disclosure is not limited thereto.

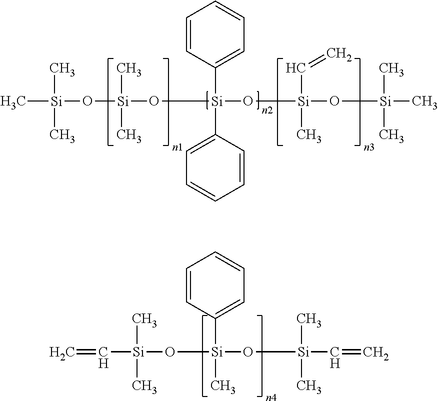

In the above formula, n1, n2 and n3 are integers of 1 or more.

The bulky compound among the silicon-vinyl compound of Formula 2 may be the following compound. However, the present disclosure is not limited thereto.

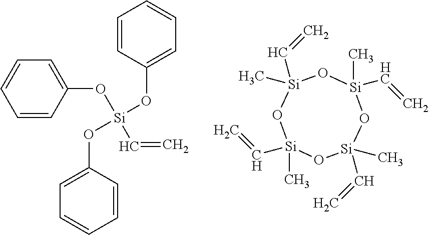 [SMILES: C=C[Si](Oc1ccccc1)(Oc1ccccc1)Oc1ccccc1 ; C=C[Si]1(C)O[Si](C)(C=C)O[Si](C)(C=C)O[Si](C)(C=C)O1]

In an embodiment, a content (e.g., amount) of the silicon-hydride based compound of Formula 3 may be less than a content (e.g., amount) of the silicon-vinyl based compound of Formula 2.

The silicon-hydride based compound of Formula 3 may be the following compound. However, the present disclosure is not limited thereto.

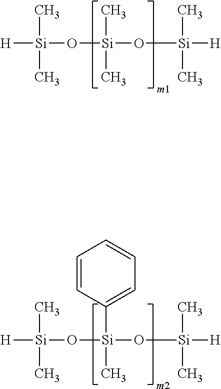

In the above formula, m1 and m2 are integers of 1 or more.

The silicon-vinyl based compound and the silicon-hydride based compound may be combined with each other under a platinum catalyst to produce the polysiloxane of Formula 1 as follows.

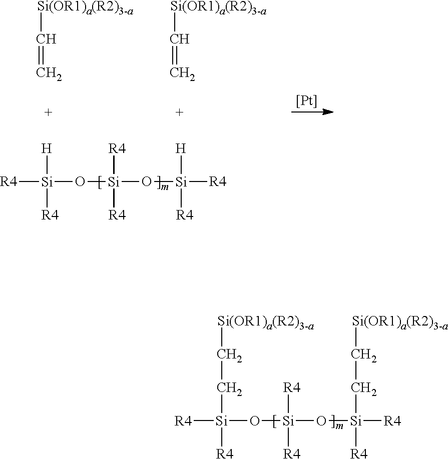

The first dam DAM1 may include one or more compounds of Formulas 1 to 3. In addition to a compound cured to the polysiloxane of Formula 3, a trace amount of compound of Formula 2 or 3 that does not participate in a reaction may remain.

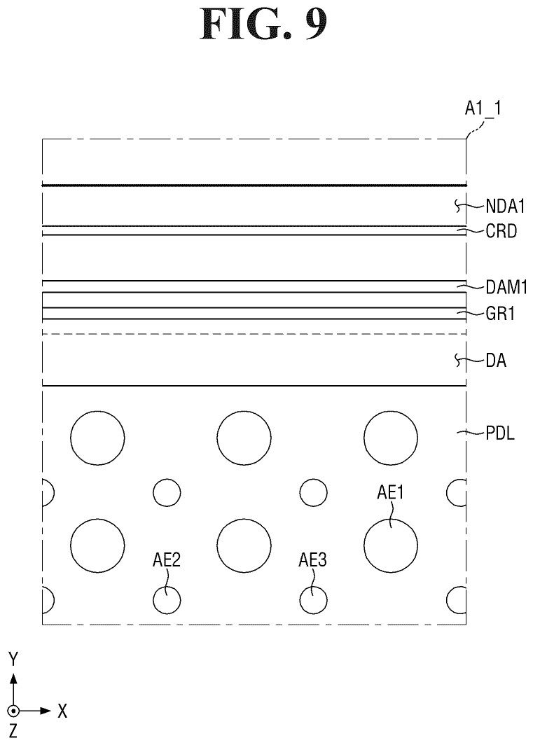

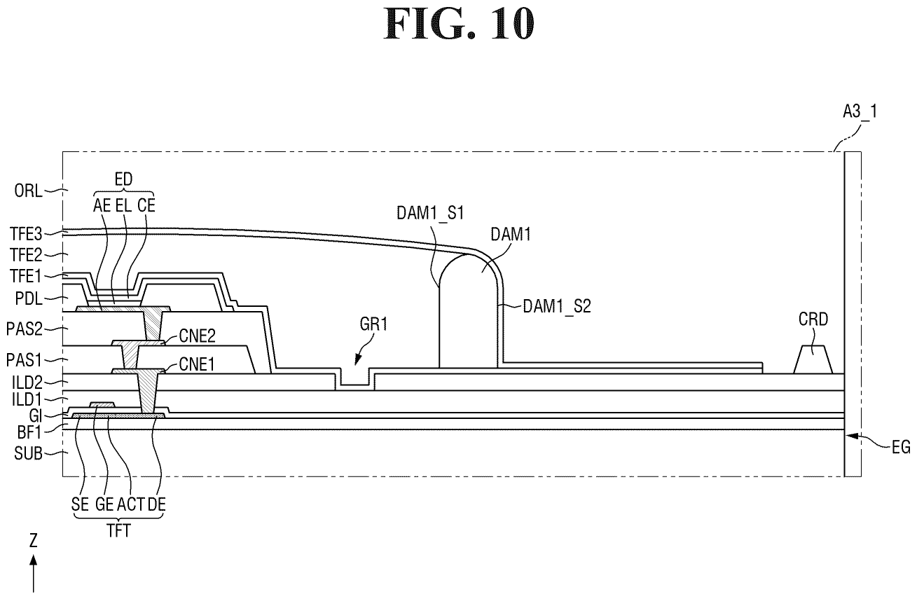

FIG. 9 is an enlarged plan view of an edge area of a display device according to another embodiment. FIG. 10 is a cross-sectional view of a display panel according to FIG. 9.

Referring to FIGS. 9 and 10, the display device 10 may further include a groove GR1 positioned inside the first dam DAM1 in the first non-display area NDA1. The groove GR1 may prevent or reduce the organic encapsulation film TFE2 from overflowing. The groove GR1 may overlap the first non-display area NDA1, and may be positioned between the light emitting element ED and the first dam DAM1. The groove GR1 may have a shape in which a portion of the thin film transistor layer TFTL is removed. The lower inorganic encapsulation film TFE1 may cover an outer surface of the groove GR1.

The crack dam CRD may be disposed outside the first dam DAM1. The crack dam CRD may be disposed close to an edge EG of the display panel 100. The crack dam CRD may be a structure for preventing or reducing cracks of the inorganic films of the thin film encapsulation layer ENC from propagating in a process of cutting the substrate SUB among processes for manufacturing the display device 10. The crack dam CRD may be disposed along left, upper, and right edges of the display panel 100. The crack dam CRD may not be disposed at a lower edge of the display panel 100. The crack dam CRD may be the outermost structure disposed at the outermost side on the left, upper and right sides of the display panel 100.

In an embodiment, the display panel 100 may include the through hole TH therein.

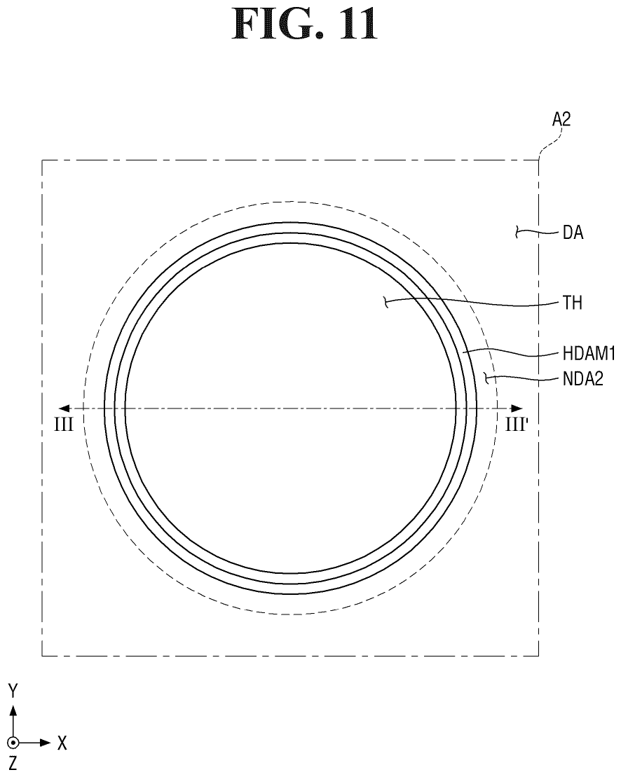

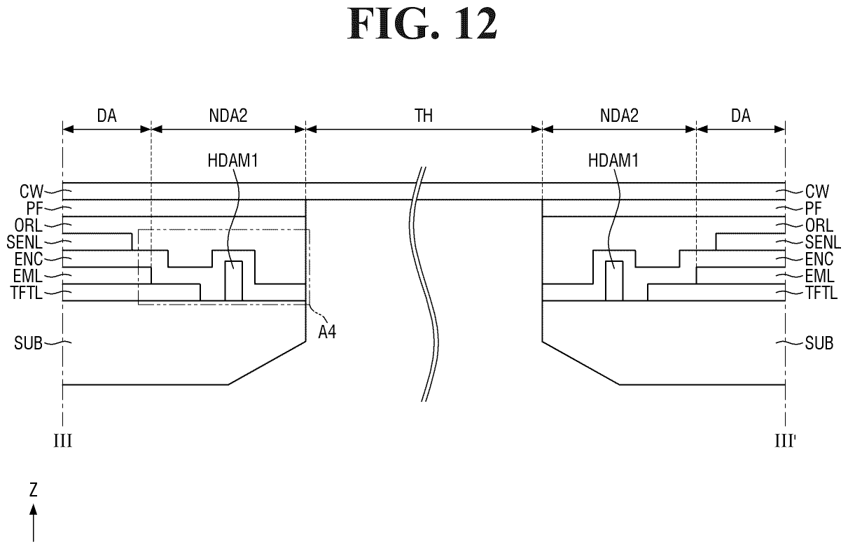

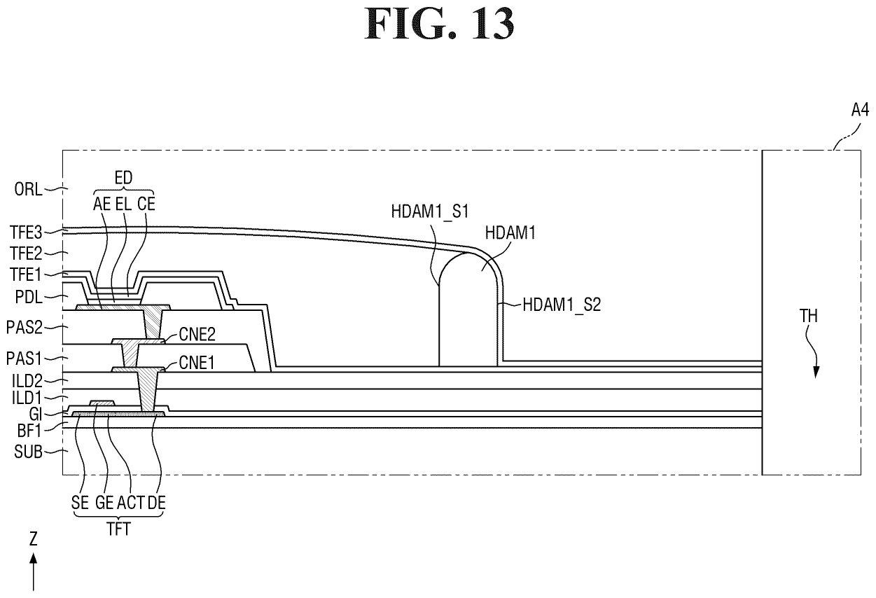

FIG. 11 is an enlarged view of a through hole TH area of the display panel. FIG. 11 is an enlarged plan view of area A2 in FIG. 2, and FIG. 12 is a cross-sectional view illustrating an example of the display device taken along line III-III′ of FIG. 11. FIG. 13 is an enlarged cross-sectional view of area A4 in FIG. 12.

Referring to FIGS. 11 to 13, the second non-display area NDA2 may be disposed to surround the through hole TH, and is positioned between the through hole TH and the display area DA.

The through hole TH may penetrate through the substrate SUB, the thin film transistor layer TFTL, the light emitting element layer EML, the thin film encapsulation layer ENC, and the touch sensor layer SENL that are included in the display panel 100, and the polarizing film PF. The through hole TH may be formed through a laser machining process. The through hole TH may be covered by the cover window CW, and the optical device OPD may be disposed inside the through hole TH.

A plurality of light emitting elements are disposed in the display area DA, but are not disposed in the second non-display area NDA2. The second non-display area NDA2 may include a first hold dam HDAM1.

The first hole dam HDAM1 may be formed in order to prevent or reduce an organic material in the display area DA from overflowing into the non-display area NDA. As an example, in the second non-display area NDA2, the organic encapsulation film TFE2 may not flow into the second non-display area NDA2 by the first hole dam HDAM1.

The first hole dam HDAM1 may be positioned to overlap the second non-display area NDA2 and surround the display area. The first hole dam HDAM1 may be disposed between the lower inorganic encapsulation film TFE1 and the upper inorganic encapsulation film TFE3.

A first side surface HDAM1_S1 of the first hole dam HDAM1 may overlap the organic encapsulation film TFE2 in the thickness direction Z of the substrate SUB. The first side surface HDAM1_S1 of the first hole dam HDAM1 may be in contact with the organic encapsulation film TFE2. The first side surface HDAM1_S1 of the first hole dam HDAM1 may be a side surface facing the display area DA.

A second side surface HDAM1_S2 of the first hole dam HDAM1 may be in contact with the upper inorganic encapsulation film TFE3. The second side surface HDAM1_S2 of the first hole dam HDAM1 may not overlap the organic encapsulation film TFE2 in the thickness direction Z of the substrate SUB. The second side surface HDAM1_S2 of the first hole dam HDAM1 may not be in contact with the organic encapsulation film TFE2. The second side surface HDAM1_S2 of the first hole dam HDAM1 is a side surface different from the first side surface HDAM1_S1, and may be a surface opposite to the first side surface HDAM1_S1. The organic encapsulation film TFE2 may be surrounded by (or blocked by) the first side surface HDAM1_S1 of the first hole dam HDAM1, and may not flow onto the second side surface HDAM1_S2 of the first hole dam HDAM1.

The first side surface HDAM1_S1 and the second side surface HDAM1_S2 of the first hold dam HDAM1 may overlap the lower inorganic encapsulation film TFE1 and the upper inorganic encapsulation film TFE3 in the thickness direction Z of the substrate SUB. The first side surface HDAM1_S1 and the second side surface HDAM1_S2 of the first hold dam HDAM1 may include not only surfaces perpendicular to the substrate SUB but also surfaces inclined with respect to the substrate SUB or curved surfaces. A lower surface of the first hole dam HDAM1 may be in contact with the lower inorganic encapsulation film TFE1.

The first hole dam HDAM1 may include polysiloxane. The polysiloxane is an organic material, and may have excellent or suitable adhesion with the organic encapsulation film TFE2 to prevent or reduce the organic encapsulation film TFE2 from overflowing the first hole dam HDAM1.

The first hold dam HDAM1 may include the same material as the first dam DAM1 of the first non-display area NDA1. The description of the first dam DAM1 may be equally applied to a material or physical properties of the first hold dam HDAM1.

The first hold dam HDAM1 may be a single layer. A component of the first hole dam HDAM1 in an area adjacent to the substrate SUB and a component of the first hole dam HDAM1 in an area adjacent to the upper inorganic encapsulation film TFE3 may be the same as each other. The first hole dam HDAM1 may overlap the light emitting element ED and the organic encapsulation film TFE2 in a first direction (e.g., a horizontal direction or an X-axis direction) of the substrate SUB.

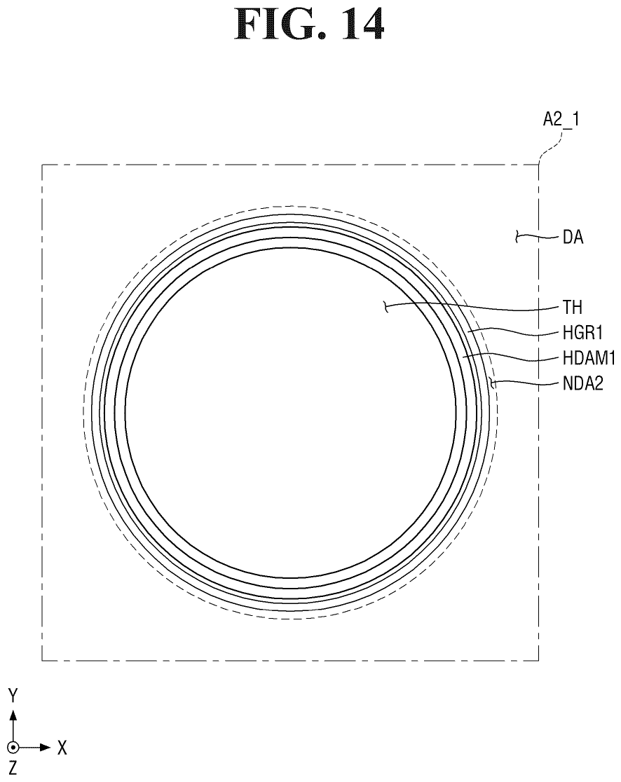

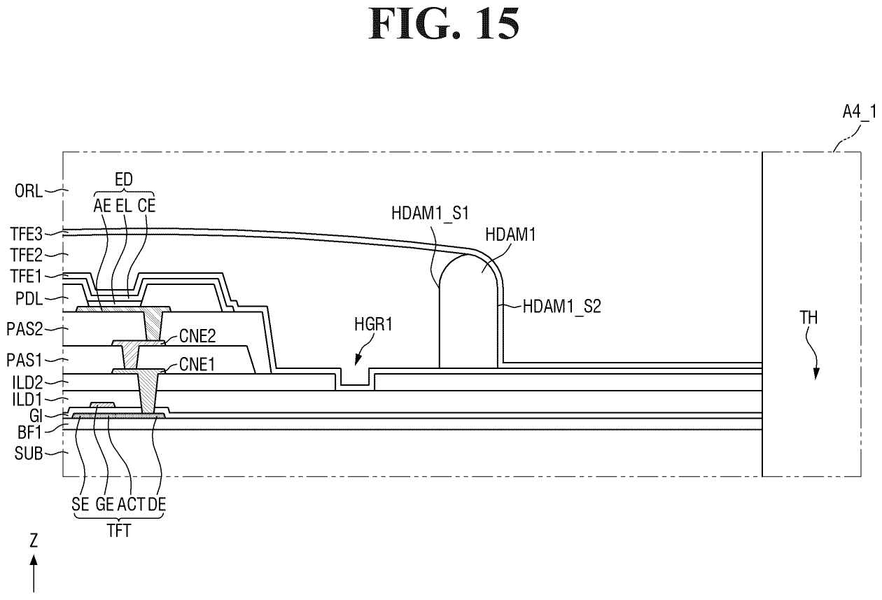

FIG. 14 is an enlarged plan view of a through hole area of a display device according to another embodiment. FIG. 15 is a cross-sectional view of a display panel according to FIG. 14.

Referring to FIGS. 14 and 15, the display device 10 may further include a hole groove HGR1 positioned inside the first hole dam HDAM1 in the second non-display area NDA2. The hole groove HGR1 may prevent or reduce the organic encapsulation film TFE2 from overflowing. The hole groove HGR1 may overlap the second non-display area NDA2, and may be positioned between the light emitting element ED and the first hole dam HDAM1. The hole groove HGR1 may have a shape in which a portion of the thin film transistor layer TFTL is removed. The lower inorganic encapsulation film TFE1 may cover an outer surface of the hole groove HGR1.

The substrate SUB may include inclined surfaces in portions overlapping the first non-display area NDA1 and the second non-display area NDA2. The inclined surface of the substrate SUB in the first non-display area NDA1 is a surface formed by a laser machining process for cutting the edge EG of the display panel 100, and may be an inclined surface in a direction toward the edge EG. The inclined surface of the substrate SUB in the second non-display area NDA2 is a surface formed by the laser machining process for forming the through hole TH, and may be an inclined surface in a direction toward the through hole TH.

Hereinafter, processes for manufacturing the display device 10 according to an embodiment will be described with reference to other drawings.

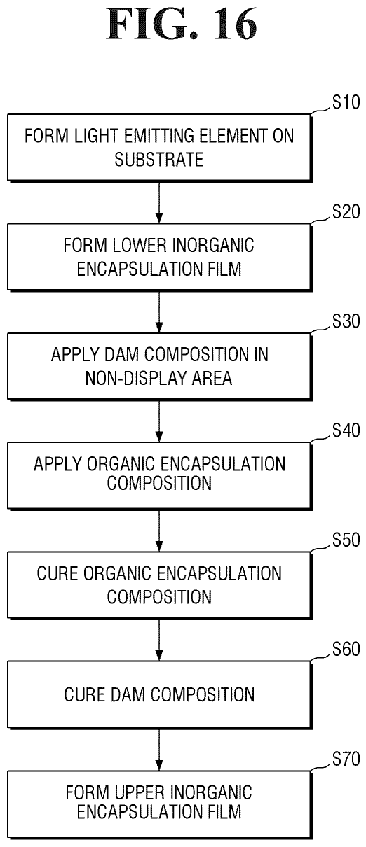

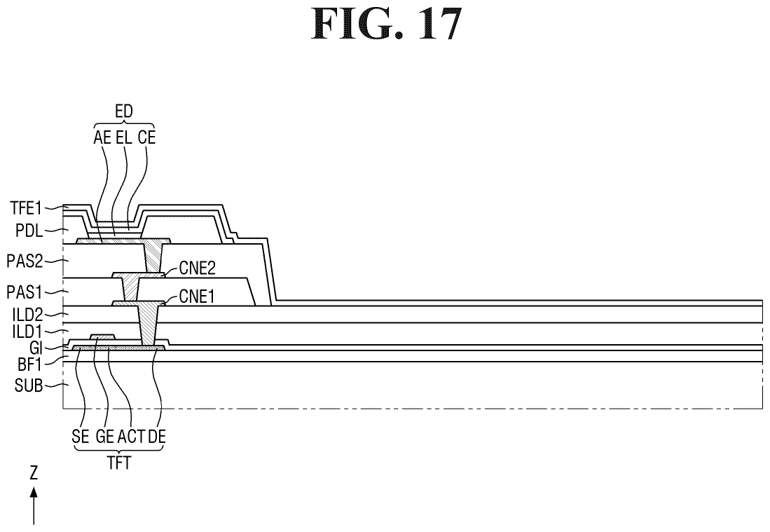

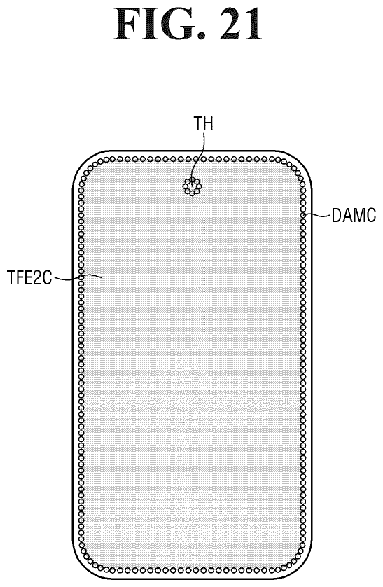

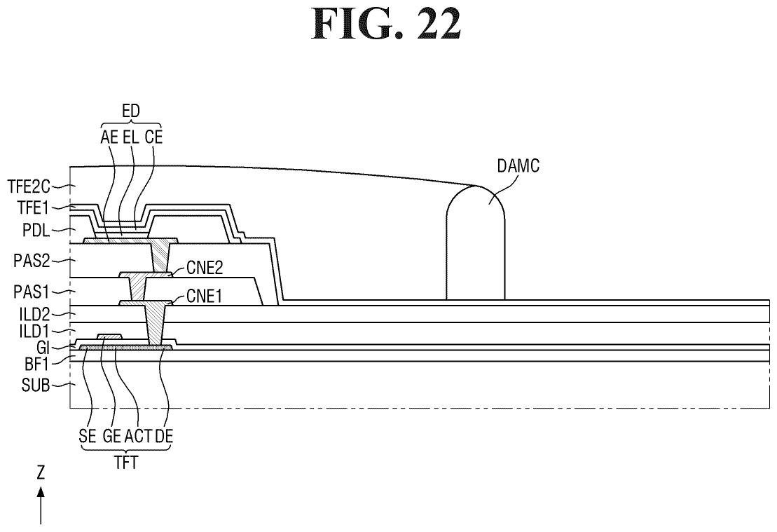

FIG. 16 is a flowchart illustrating processes for manufacturing the display device 10 according to an embodiment, and FIGS. 17 to 25 are cross-sectional views or plan views schematically illustrating the processes for manufacturing the display device according to an embodiment. Hereinafter, the formation of the dam DAM1 and the organic encapsulation film TFE2 in the first non-display area NDA1 will be mainly described, and a description of other layers and areas will not be provided.

Referring to FIG. 17, the substrate SUB on which the light emitting element ED and the lower inorganic encapsulation film TFE1 are provided in the display area DA is prepared. The light emitting elements ED are formed in the display area DA of the substrate SUB, and the lower inorganic encapsulation film TFE1 is then deposited not only on the display area DA but also on the non-display area NDA.

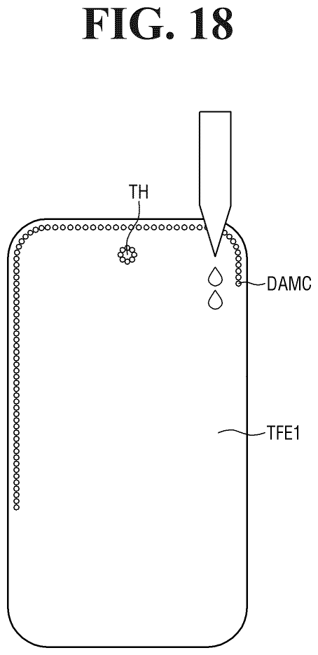

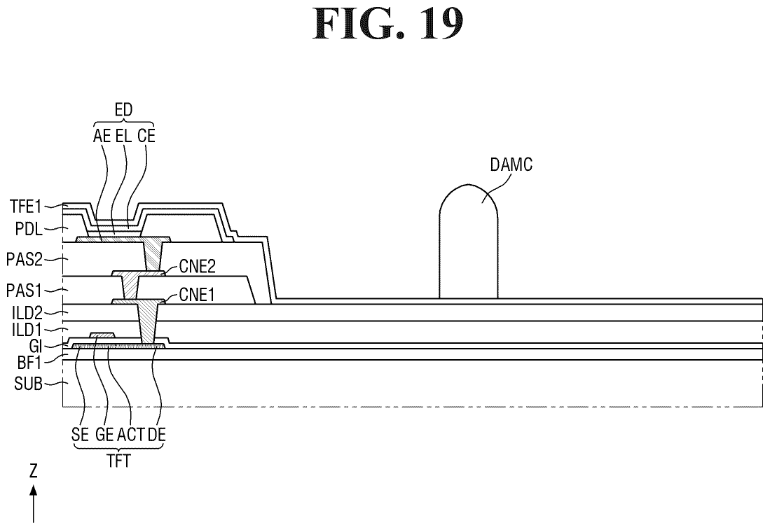

Next, referring to FIGS. 18 and 19, a dam composition DAMC is applied onto the lower inorganic encapsulation film in the non-display area NDA. The non-display area NDA is an area disposed around the display area DA, and may include the first non-display area NDA1 and the second non-display area NDA2. When the groove GR1 exists in the first non-display area NDA1, the dam composition DAMC is applied outside the groove GR1. When the hole groove HGR1 exists in the second non-display area NDA2, the dam composition DAMC is applied outside the hole groove HGR1, that is, between the hole groove HGR1 and the through hole TH.

In a step of applying the dam composition DAMC, a jet dispenser may be utilized. The dam composition may have a much higher viscosity than an organic encapsulation composition to be described later. The dam composition may have a high viscosity, and be thus maintained in a form in which it is discharged form without spreading even after being discharged utilizing the jet dispenser.

In an embodiment, the dam composition DAMC may include the silicon-vinyl based compound represented by the above-described Formula 2 and the silicon-hydride based compound represented by the above-described Formula 3. The silicon-vinyl based compound may include a linear form and a bulky form. A content (e.g., amount) of the bulky silicon-vinyl based compound may be more than a content (e.g., amount) of the linear silicon-vinyl based compound. A content (e.g., amount) of the silicon-hydride based compound may be more than a content (e.g., amount) of the silicon-vinyl based compound.

In an embodiment, the dam composition DAMC may further include a solvent, a catalyst, and additives. The dam composition DAMC may include a platinum (Pt) catalyst.

In an embodiment, the dam composition DAMC may include about 5 wt % to about 25 wt % of the linear silicon-vinyl based compound, about 30 wt % to about 80 wt % of the bulky silicon-vinyl based compound, and about 0.5 wt % to about 20 wt % of the silicon-hydride based compound based on the total weight of the dam composition.

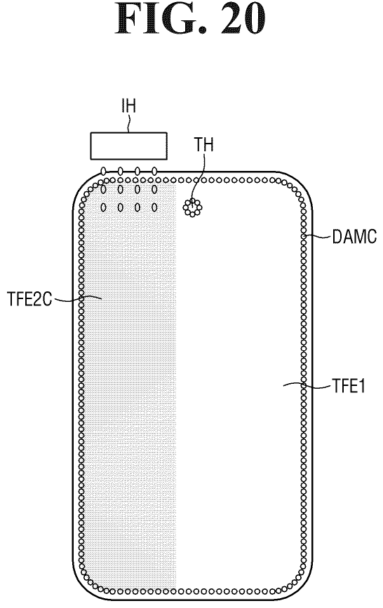

Next, referring to FIGS. 20 to 22, an organic encapsulation composition TFE2C is applied onto the lower inorganic encapsulation film TFE1. The organic encapsulation composition TFE2C is applied to the non-display area NDA inside the applied dam composition DAMC and the display area DA. The organic encapsulation composition TFE2C is not applied beyond the dam composition DAMC.

In an embodiment, in a step of applying the organic encapsulation composition TFE2C, an inkjet printer may be utilized. A viscosity of the organic encapsulation composition TFE2C may be much lower than the viscosity of the dam composition DAMC. The organic encapsulating composition TFE2C may be ink ejected from an inkjet head IH and then spread.

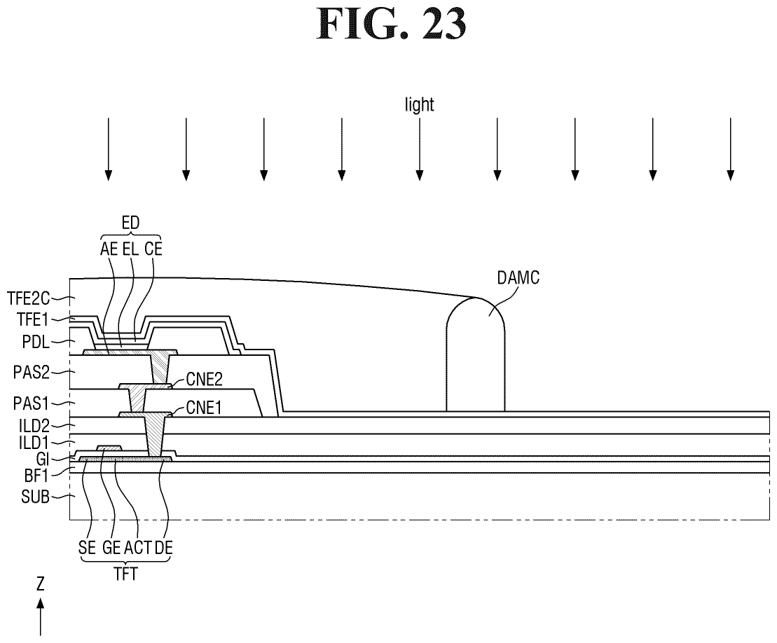

Next, referring to FIG. 23, the organic encapsulation composition TFE2C is cured to form the organic encapsulation film TFE2. In an embodiment, the organic encapsulation composition TFE2C may be cured by light.

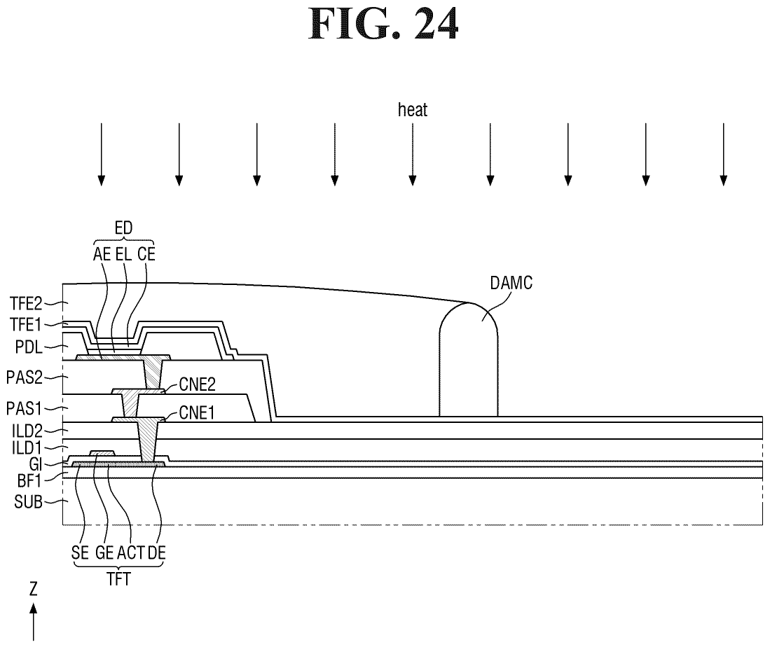

Next, referring to FIG. 24, the dam composition DAMC may be cured to form a dam DAM. The silicon-vinyl based compound and the silicon-hydride based compound included in the dam composition DAMC may be combined with each other to form the polysiloxane. In an embodiment, the dam composition DAMC may be cured by heat.

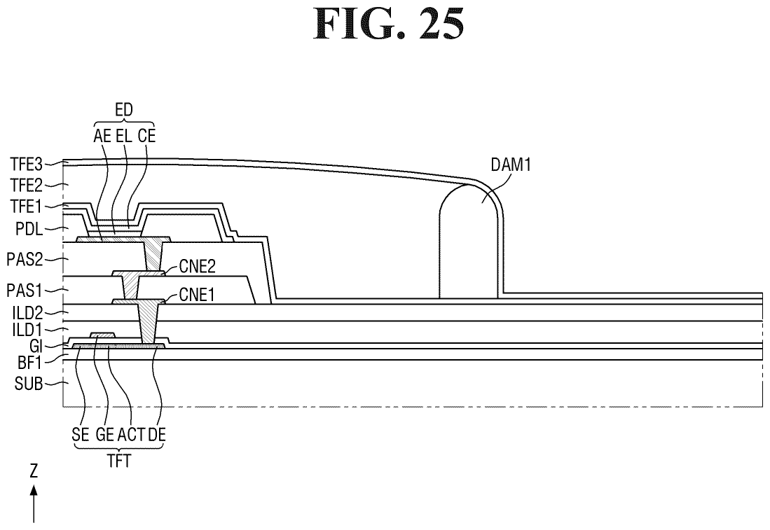

Next, referring to FIG. 25, the upper inorganic encapsulation film TFE3 is deposited on the dam DAM and the organic encapsulation film TFE2. In an embodiment, the upper inorganic encapsulation film TFE3 may be formed by chemical vapor deposition (CVD).

In the present disclosure, singular expressions may include plural expressions unless the context clearly indicates otherwise. It will be further understood that the terms “comprise(s),” “include(s),” or “have/has” when utilized in the present disclosure, specify the presence of stated features, integers, steps, operations, elements, and/or components, but do not preclude the presence or addition of one or more other features, integers, steps, operations, elements, components, and/or groups thereof. The “/” utilized herein may be interpreted as “and” or as “or” depending on the situation.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, when particles (e.g., nanoparticles) are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In present disclosure, “not include a or any ‘component’” “exclude a or any ‘component’”, “‘component’-free”, and/or the like refers to that the “component” not being added, selected, or utilized as a component in a compound/composition, but the “component” of less than a suitable amount may still be included due to other impurities and/or external factors in a composition.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In concluding the detailed description, those skilled in the art will appreciate that many variations and modifications can be made to the preferred embodiments without substantially departing from the principles of the present disclosure. Therefore, the disclosed preferred embodiments of the present disclosure are utilized in a generic and descriptive sense only and not for purposes of limitation.

What is claimed is:

1. A display device comprising:
a substrate comprising a display area and a first non-display area around the display area;
a light emitting element on the display area of the substrate in the display area;
a lower inorganic encapsulation film on the substrate in the display area and the first non-display area;
an organic encapsulation film on the lower inorganic encapsulation film;
an upper inorganic encapsulation film on the organic encapsulation film; and
a first dam between the lower inorganic encapsulation film and the upper inorganic encapsulation film in the first non-display area,
wherein a first side surface of the first dam is in contact with the organic encapsulation film, and
a second side surface of the first dam different from the first side surface of the first dam is in contact with the upper inorganic encapsulation film.

2. The display device of claim 1, wherein a lower surface of the first dam is in contact with the lower inorganic encapsulation film.

3. The display device of claim 1, wherein the first dam comprises polysiloxane.

4. The display device of claim 3, wherein a glass transition temperature of the first dam is about −180° C. to about −50° C.

5. The display device of claim 3, wherein a density of the first dam is about 0.05 g/mL to about 5 g/mL.

6. The display device of claim 1, wherein a Young's modulus of the first dam is about 0.01 MPa to about 1.0 MPa.

7. The display device of claim 3, wherein the first dam comprises a compound represented by any one selected from among Formulas 1 to 3: 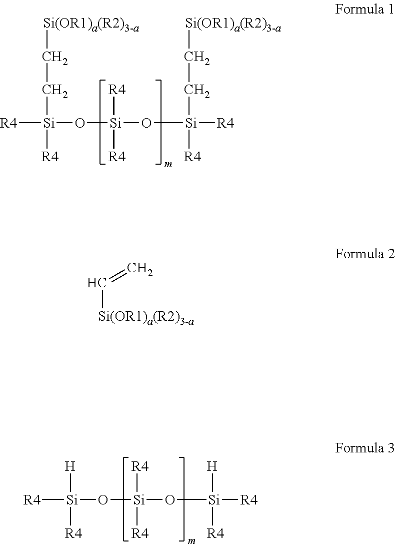
wherein a is an integer of 1 to 3,
m is an integer of 1 or more,
R1 is a substituted or unsubstituted alkyl group, a substituted or unsubstituted aryl group, or is represented by Formula S1, 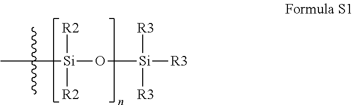
n is an integer of 1 or more,
R2 to R4 are the same as or different from each other, and are each independently a substituted or unsubstituted alkyl group, a substituted or unsubstituted aryl group, a substituted or unsubstituted alkenyl group, or an oxygen atom, and/or are connected to an adjacent substituent to form a substituted or unsubstituted ring, and
a substituent in the substituted or unsubstituted groups is one or more substituents selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group, and/or a substituent in which two or more groups selected from the group are connected to each other.

8. The display device of claim 1, further comprising a groove positioned between the light emitting element and the first dam.

9. The display device of claim 1, wherein the substrate further comprises a through hole and a second non-display area between the through hole and the display area,
the display device further comprises a first hole dam between the lower inorganic encapsulation film and the upper inorganic encapsulation film in the second non-display area,
a first side surface of the first hole dam is in contact with the organic encapsulation film, and
a second side surface of the first hole dam different from the first side surface of the first hole dam is in contact with the upper inorganic encapsulation film.

10. The display device of claim 9, wherein the first hold dam comprises the same material as the first dam.

11. The display device of claim 9, further comprising a hole groove positioned between the light emitting element and the first hold dam.

12. A display device comprising:
a substrate comprising a display area and a first non-display area around an outer side of the display area;
a lower inorganic encapsulation film on the substrate in the display area and the first non-display area;
an organic encapsulation film on the lower inorganic encapsulation film;
a first dam on the substrate in the first non-display area and comprising polysiloxane; and
an upper inorganic encapsulation film on the organic encapsulation film and the first dam,
wherein a first side surface of the first dam overlaps the organic encapsulation film in a plan view of the substrate, and
a second side surface of the first dam different from the first side surface of the first dam does not overlap the organic encapsulation film in the thickness direction of the substrate.

13. The display device of claim 12, wherein the first side surface and the second side surface of the first dam overlap the upper inorganic encapsulation film and the lower inorganic encapsulation film in the thickness direction of the substrate.

14. The display device of claim 1, wherein a component of the first dam in an area adjacent to the substrate and a component of the first dam in an area adjacent to the upper inorganic encapsulation film are the same as each other.

15. The display device of claim 12, wherein the first dam comprises a compound represented by any one of Formulas 1 to 3: 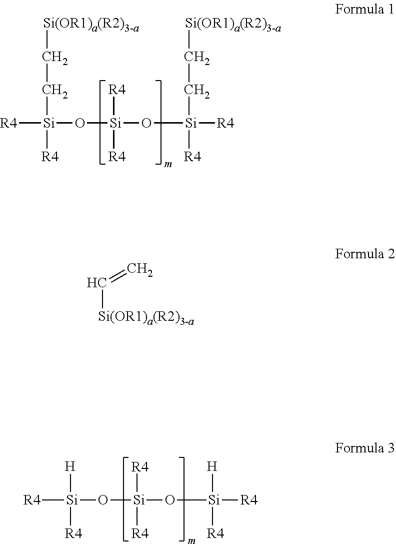
wherein a is an integer of 1 to 3,
m is an integer of 1 or more,
R1 is a substituted or unsubstituted alkyl group, a substituted or unsubstituted aryl group, or is represented by Formula S1, 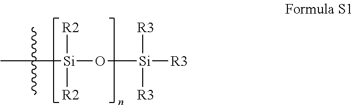
n is an integer of 1 or more,
R2 to R4 are the same as or different from each other, and are each independently a substituted or unsubstituted alkyl group, a substituted or unsubstituted aryl group, a substituted or unsubstituted alkenyl group, or an oxygen atom, and/or are connected to an adjacent substituent to form a substituted or unsubstituted ring, and
a substituent in the substituted or unsubstituted groups is one or more substituents selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group, and/or a substituent in which two or more groups selected from the group are connected to each other.

16. A method for manufacturing a display device, the method comprising:
applying light emitting elements on a substrate;
depositing a lower inorganic encapsulation film on the light emitting elements;
applying a dam composition onto the lower inorganic encapsulation film in a non-display area around a display area in which the light emitting elements are; and
applying an organic encapsulation composition onto the lower inorganic encapsulation film in the display area.

17. The method for manufacturing a display device of claim 16, wherein a viscosity of the dam composition is greater than a viscosity of the organic encapsulation composition.

18. The method for manufacturing a display device of claim 16, wherein in the applying of the dam composition onto the lower inorganic encapsulation film, a jet dispenser is utilized.

19. The method for manufacturing a display device of claim 16, further comprising:
curing the organic encapsulation composition to form an organic encapsulation film;
curing the dam composition to form a dam; and
depositing an upper inorganic encapsulation film on the organic encapsulation film and the dam.

20. The method for manufacturing a display device of claim 19, wherein in the curing of the organic encapsulation composition to form the organic encapsulation film, the organic encapsulation composition is cured utilizing light, and
in the curing of the dam composition to form the dam, the dam composition is cured utilizing heat.
